(19) United States
(12) Patent Application Publication
(10) Pub. No.: US 2010/0178726 A1
(43) Pub. Date: Jul. 15, 2010

(54) Conductive Paste, Solar Cell Manufactured Using Conductive Paste, Screen Printing Method and Solar Cell Formed Using Screen Printing Method

(75) Inventors: Tomonari SAKAMOTO, Shiga (JP); Kazuteru HISAMOTO, Kagoshima (JP); Hirotoshi ETOU, Kagoshima (JP)

Correspondence Address: Hogan Lovells US LLP, 1999 AVENUE OF THE STARS, SUITE 1400, LOS ANGELES, CA, 90067, US

(73) Assignee: KYOCERA CORPORATION, Kyoto-shi (JP)

(21) Appl. No.: 12/725,289

(22) Filed: Mar. 16, 2010

Related U.S. Application Data
(62) Division of application No. 11/458,652, filed on Jul. 19, 2006.

(30) Foreign Application Priority Data
Jul. 19, 2005 (JP) 2005-208419
Aug. 30, 2005 (JP) 2005-249319

(51) Int. Cl. H01L 31/18; H01L 21/3205

(52) U.S. Cl. 438/98; 257/E31.119; 257/E21.295

(57) ABSTRACT

The conductive paste contains a conductive metal powder and an organic vehicle. The conductive paste has characteristics that the viscosity falls within the range of 200 Pa·s to 350 Pa·s when the shear rate of 10 s⁻¹ is applied and within the range of 80 Pa·s to 120 Pa·s when the shear rate of 40 s⁻¹ is applied under 25° C. and magnitudes of a storage elastic modulus G′ and a loss elastic modulus G″ are reversed when distortion applied to the conductive paste at the frequency of 1 Hz is varied from 0 to 20%.

This application is based on application Nos. JP2005-208419 and JP2005-249319 filed in Japan, the contents of which are hereby incorporated by reference.

### BACKGROUND OF THE INVENTION

1. Field of the invention

The present invention relates to a screen printing method, a solar cell formed using the screen printing method, a method for forming a printing substrate on which a conductor circuit represented by a solar cell, especially a method for manufacturing a solar cell using a conductive paste for printing.

2. Description of the Background Art

FIG. 6 shows a conventional screen printing method.

First, a scraper 101 is lowered on the screen 103 and a paste 104 located at one end of the screen 103 (printing termination end) is moved to the other end (printing starting end). At this time, a part of the paste 104 is filled into a pattern hole 103a of the screen 103.

Next, the scraper 101 rises and an object to be printed is sent to a position about 0.5 to 3 min away from the back surface of the screen 103. Then, a squeegee for printing (that is, a printing squeegee) 102 is pressed against the screen 103, thereby allowing the screen 103 to contact with the object to be printed. By moving the printing squeegee 102 in a direction opposite to the scraper 101 in this contact state, the paste (that is, the paste filled into pattern hole 103a) 104 is printed on the object to be printed. At this time, unprinted paste 104 is collected by the printing squeegee 102.

Then, when the printing squeegee 102 rises, a series of operations are finished.

When a next object to be printed exists, the above-mentioned series of operations are performed repeatedly.

However, to reduce cycle time of printing for improving productivity according to the above-mentioned printing method, the moving speed of the scraper during printing needs to be increased. However, since the process time for filling the paste into the pattern hole of the screen becomes shorter as the moving speed of the scraper is increased, the paste cannot be fully filled into the pattern hole, causing a problem that a desired printing result (that is, printing shape) cannot be obtained in some cases.

For example, in printing wiring on the object to be printed by use of the conductive paste, when the thickness of the wiring partially becomes thinner due to the above-mentioned problem, a resistance value of the wiring becomes larger, thereby leading to functional disorder of the wiring such as generation of heat. Especially when high-density wiring is printed, the paste is forced to be filled into the relatively thin pattern hole. Thus, it is extremely difficult to increase the moving speed of the scraper.

Conventional methods of forming a conductor circuit on the surface of the substrate by using the conductive paste include a screen printing method, a drawing method of drawing a circuit with a pen and an etching method of applying a predetermined material for forming a circuit over the surface of the substrate (that is, a circuit-forming material) and then forming the circuit by etching. However, since the screen printing method is superior to the other methods in productivity, reliability, etc., the screen printing method having excellent reproducibility of thin wiring (that is, thin lines) is used in most cases where the conductor circuit is formed on the surface of the substrate by using the conductive paste.

Typical conductive paste includes a mixture of an organic vehicle generated by dissolving resin in a solvent and metal powders having conductivity (that is, a conductive metal powder) in a dispersed state. Such typical conductive paste is printed on the substrate according to the screen printing method by using a screen having a pattern hole for printing (that is, a printing pattern hole) and a resin squeegee and burning the conductive paste, conductive wiring having a width of about 100 μm can be formed on the substrate. Such conductive wiring is used as a collecting electrode provided on the surface of a solar cell and a thick film circuit on a ceramic substrate.

However, when the general conductive paste film is formed on the substrate according to the general screen printing method by using the screen having the printing pattern hole and the resin squeegee as described above, bleeding occurs in the printed figure (that is, the printing shape formed by the conductive paste) and/or clogging occurs in the mesh part of the screen.

These problems becomes pronounced especially when the manufacturer attempts to make a minute pattern of the conductor circuit and causes failure of wiring due to a break in the circuit as well as variation in and defects of characteristics of the solar cell.

It is considered that printing bleeding (that is, bleeding in the printed figure) is caused by the amount of the conductive paste filled into the printing pattern hole and the viscosity of the conductive paste at the time of leveling (that is, at the time of smoothing the upper face of the conductive paste immediately after printing). It is considered that the viscosity at the time of leveling is mainly dominated by an elastic component in the viscosity of the conductive paste when the conductive paste is relieved from high shear rate during printing and subjected to low shear rate during leveling. It is considered that the clogging of the mesh part is caused by a release property of the conductive paste filled into the printing pattern hole, that is, a viscous component in the viscosity of the conductive paste under the shear rate applied when the conductive paste is transferred to the substrate. Under low shear rate at the time of leveling, when the shear rate is applied to the conductive paste, configuration changes in a linearly responding region (that is, a region where distortion generated in the conductive paste linearly responds to stress) and thus, an effect of the ratio of the viscous component and the elastic component forming the viscosity of the conductive paste on the ease of leveling (leveling property) becomes prominent. When the viscosity of the paste is measured with various shear rate and natural logarithms of values of the shear rate and the viscosity are taken to form a graph, the graph represents a nearly straight line. Accordingly, to solve the above-mentioned problems during printing, it is important to control the viscosity of the conductive paste at the time of filling, transferring, separating from the plate and leveling. Thus, it is necessary to control the inclination of the above-mentioned graphed line and the ratio of the viscous component and the elastic component in the viscosity of the conductive paste in the linearly responding region of the conductive paste.

There is disclosed a conductive paste containing the conductive metal powder and the organic vehicle, in which, under 25 degrees C. (25° C.), the viscosity at the shear rate of 500 s⁻¹ falls within the range of 1.0 Pa·s to 10 Pa·s, the viscosity at the shear rate of 10 s⁻¹ falls within the range of 5 Pa·s to 20 Pa·s and the ratio of the storage elastic modulus G′ and the loss elastic modulus G″ (G″/G′=tan δ) measured by varying the distortion applied to the conductive paste under the frequency of 1 Hz in the linearly responding region of the conductive paste falls within the range of 2.0 to 8.0 (for example, Japanese Patent Application Laid-Open No. 2003-124052). However, for example, when the conductive paste is printed on the substrate to form electrodes of the solar cell, since the viscosity is low and the viscous component is much larger than the elastic component, dripping occurs in a coated film (that is, a coated film formed by printing the conductive paste) after printing. Accordingly, large bleeding is generated and electrodes with enough thickness cannot be formed.

To take power obtained when sunlight enters into the solar cell to the outside without loss, resistance loss in the electrodes needs to be suppressed by making the cross-section area of the electrodes provided on the solar cell larger. Furthermore, for the electrodes provided on the light-receiving surface of the solar cell, to ensure enough light-receiving area, it is important to make the line width narrower and the thickness larger. As described above, when the above-mentioned conductive paste is printed on the substrate, the light-receiving area is decreased due to large bleeding that occurs in the coated film after printing and enough thickness of the electrodes cannot be obtained, thereby increasing resistance loss of the electrodes. Thus, the solar cell having high conversion efficiency cannot be manufactured.

### SUMMARY OF THE INVENTION

The present invention is directed to a conductive paste. According to the present invention, the conductive paste contains conductive metal powder and an organic vehicle and has characteristics that a viscosity falls within a range of 200 Pa·s to 350 Pa·s when a shear rate of 10 s⁻¹ is applied and within a range of 80 Pa·s to 120 Pa·s when a shear rate of 40 s⁻¹ is applied under 25° C. and magnitudes of a storage elastic modulus G′ and a loss elastic modulus G″ are reversed when distortion applied to the conductive paste at a frequency of 1 Hz is varied from 0 to 20%.

It is possible to suppress bleeding of the conductive paste and clogging of the conductive paste in a mesh part during printing, easily make the printing paste (that is, the conductive paste printed on an object to be printed) thicker and improve deficiency in printing.

The present invention is also directed to a solar cell manufactured by using the conductive paste.

The present invention is also directed to a screen printing method. According to the present invention, the screen printing method includes the steps of: (a) spreading a paste on a screen by using a scraper so as to cover a pattern hole provided on the screen, (b) filling the paste spread over the screen into the pattern hole by using a filling squeegee and (c) printing the paste filled into the pattern hole on an object to be printed by using a printing squeegee.

Since the filling squeegee only serves to fill the paste previously spread over the screen by using an another member (that is, the scraper) into the pattern hole, the filling processing can be performed very efficiently, resulting in substantial reduction in processing time.

The present invention is also directed to a solar cell formed according to the screen printing method.

Therefore, an object of the present invention is to provide an art of preventing bleeding of the conductive paste and clogging of the conductive paste in a mesh part in screen printing and easily making the printing paste (that is, the conductive paste printed on the object to be printed) thicker while obtaining printing wiring with high accuracy.

Another object of the present invention is to provide a solar cell manufactured by using the conductive paste capable of preventing bleeding of the conductive paste and clogging of the conductive paste in a mesh part in screen printing and easily making the conductive paste printed on the object to be printed thicker while obtaining printing wiring with high accuracy.

Another object of the present invention is to provide a screen printing method of obtaining a printed matter having stable shape and thickness of the printed paste in spite of short printing time.

Another object of the present invention is to provide a solar cell manufactured according to a screen printing method of obtaining a printed matter having stable shape and thickness of the printed paste in spite of short printing time.

These and other objects, features, aspects and advantages of the present invention will become more apparent from the following detailed description of the present invention when taken in conjunction with the accompanying drawings.

### BRIEF DESCRIPTION OF THE DRAWING

FIG. 1A to FIG. 1C are sectional views for describing a screen printing method in accordance with a preferred embodiment of the present invention. Specifically, FIG. 1A is a view showing a first step of spreading a paste on a screen by using a scraper so as to cover a pattern hole provided on the screen, FIG. 1B is a view showing a second step of filling the paste spread over the screen into the pattern hole by using a filling squeegee and FIG. 1C is a view showing a third step of printing the paste filled into the pattern hole on an object to be printed by using a printing squeegee.

FIG. 2 is a view showing a screen printer used in the screen printing method in accordance with the preferred embodiment of the present invention, especially the screen printer in which the filling squeegee and the scraper are not fixed to each other.

FIG. 3 is a plan view showing a solar cell formed by the screen printing method in accordance with the preferred embodiment of the present invention.

FIG. 4 is a view showing configuration of a cross section of the solar cell in accordance with the preferred embodiment of the present invention.

FIG. 5A and FIG. 5B are views showing an example of shape of electrodes of the solar cell in accordance with the preferred embodiment of the present invention.

Specifically, FIG. 5A is a view showing the shape of the electrodes on the side of a light-receiving surface (front surface) and FIG. 5B is a view showing the shape of the electrodes on the side of a non-light-receiving surface (back surface).

FIG. 6 is a view showing a screen printer used in a conventional screen printing method.

### DESCRIPTION OF THE PREFERRED EMBODIMENTS

Hereinafter, a preferred embodiment of the present invention will be described in detail with reference to figures.

### <Ideas About Screen Printing Method>

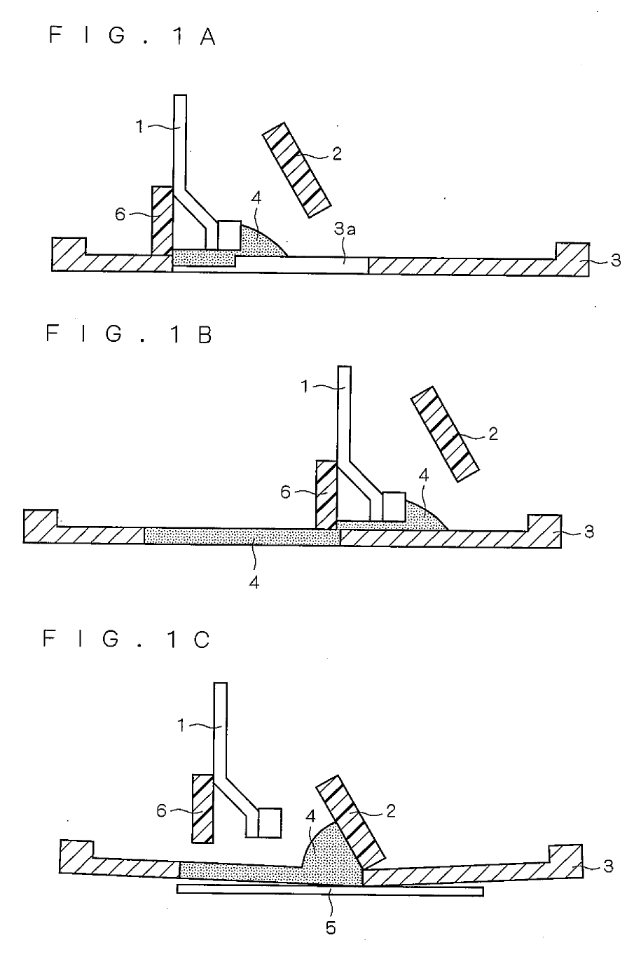

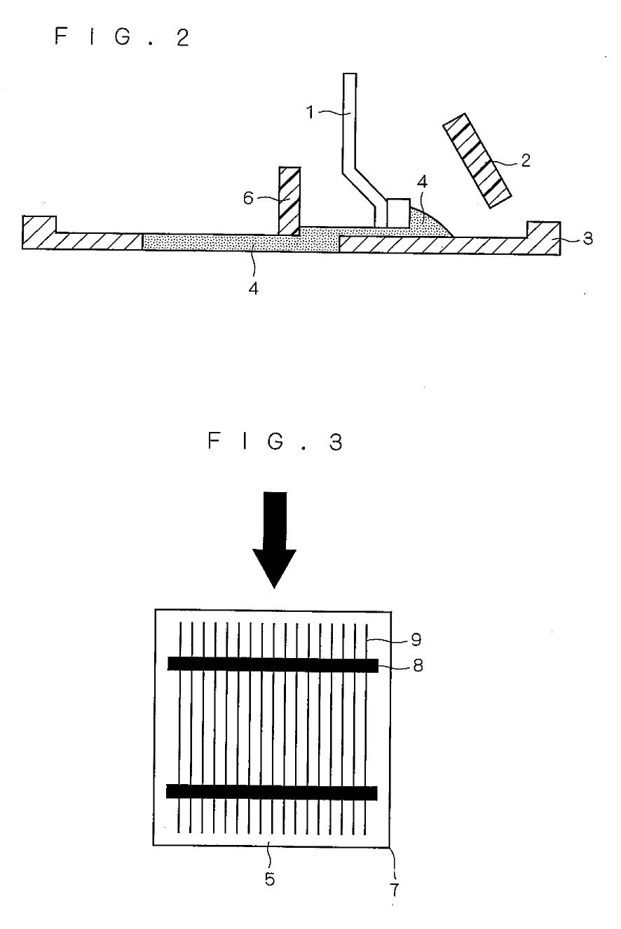

A preferred embodiment of a printing method of the present invention will be described with reference to FIG. 1 A to FIG. 1C. FIG. 1A to FIG. 1C are views showing first to third steps in a screen printing method in accordance with the preferred embodiment of the present invention, respectively. These figures show a scraper 1, a printing squeegee 2, a screen 3, a pattern hole 3a, a paste 4, an object to be printed 5 and a filling squeegee 6. A screen printer used in the screen printing method in accordance with this embodiment has mainly a scraper 1, a first squeegee 2, a screen 3 and the second squeegee 6, and prints the paste 4 on the object to be printed 5 via the screen 3 provided with the pattern hole 3a. The scraper 1 is a member for spreading the paste 4 on the surface of the screen 3. The second squeegee 6 is a squeegee (also referred to as the “filling squeegee”) for filling the paste 4 into the pattern hole 3a formed on the screen 3. The screen 3 is a member having the pattern hole 3a corresponding to the paste 4 printed on the object to be printed 5 in shape. The first squeegee 2 is a squeegee (also referred to as the “printing squeegee”) for allowing the paste 4 filled into the pattern hole 3a to be printed on the object to be printed 5. Hereinafter, the case where a semiconductor substrate for a solar cell is used as the object to be printed 5 will be described. That is, the case where a paste having conductivity (hereinafter referred to as “conductive paste”) is used as the paste 4 will be described.

In this embodiment, the filling squeegee 6 is fixed to the scraper 1 and they operate in sync with each other. That is, the filling squeegee 6 and the scraper 1 move nearly simultaneously. Such configuration enables relatively simple and light-weighted configuration. Accordingly, even when the filling squeegee 6 is moved at high speed, stable operation can be achieved and thus, the accuracy of printing can be improved. In this case, the moving speed of the filling squeegee 6 and the scraper 1 do not necessarily have to be the same and only need be set according to the viscosity of the paste 4.

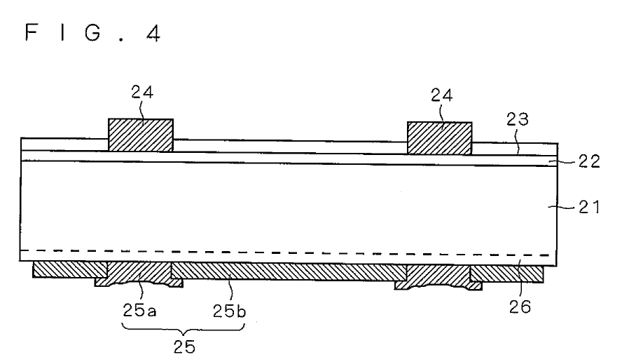

It is needless to say that the filling squeegee 6 need not be fixed to the scraper 1 but to be operable independently from the scraper I as shown in FIG. 2. The first to third steps in the screen printing method in accordance with this embodiment will be described hereinafter, respectively.

<First Step>

As shown in FIG. 1A, the scraper 1 disposed in nearly parallel with the surface of the screen 3 lowers with the filling squeegee 6. That is, the scraper 1 and the filling squeegee 6 lower toward the surface of the screen 3. The scraper 1 moves in nearly parallel with the surface of the screen 3, so that the paste is spread over the surface of the screen 3 substantially smoothly.

Here, the distance between the screen 3 and the scraper 1 may be appropriately set according to the viscosity of the paste 4, for example, 0.05 mm to 3.0 mm. That is, a predetermined value may be set in the range of about 0.05 mm to 3.0 mm.

As a means for moving the scraper 1 and the filling squeegee 6 in the horizontal direction, for example, an air cylinder or a motor may be used. To spread the paste 4 on the surface of the screen 3 substantially smoothly, it is preferred that no oscillation occurs in the scraper 1 and the filling squeegee 6. By employing the configuration that causes no oscillation in the scraper 1 and the filling squeegee 6, even when the screen 3 having a minute pattern hole 3a is used, the scraper 1 and the filling squeegee 6 can apply a desired pressure to the paste 4, thereby preventing lack in the filling of the paste 4 into the pattern hole 3a.

Here, the scraper 1 needs to have enough rigidity to spread the paste 4 on the surface of the screen 3 against the viscosity of the paste 4. For example, iron is preferably used as a material for the scraper 1. More preferably, a material having corrosion resistance and chemical resistance, such as stainless, is used. Alternatively, the surface of the screen 3 may be coated with resin having corrosion resistance and chemical resistance. To improve smoothness of the paste 4 spread over the surface of the screen 3, a surface of the scraper 1, which is opposed to the screen 3, has a maximum surface roughness (Ry) of 1 μm or less preferably, 0.5 μm or less more preferably.

As the paste 4, a mixture of conductive metal powder made of silver, aluminum or the like and an organic vehicle made of an organic binder and an organic solvent may be used.

The organic binder used to form the paste 4 includes cellulosic, acrylic, butyral resin or the like and the organic solvent includes butyl carbitol, butyl carbitol acetate, buthyl cellosolve, buthyl cellosolve acetate, terpinenol, hydrogenated terpinenol, hydrogenated terpineol acetate, methyl ethyl ketone, isobornyl acetate, nopyl acetate or the like. Since the organic binder and the organic solvent are dissolved and vaporized at about 400° C., these components do not remain in electrodes after burning.

Glass powder may be contained in the paste 4. The glass powder contains an oxide of lead, boron, silicon or the like and has various softening points in the range of about 300 to 600° C. A part of the glass powder remains in the electrodes after burning of the paste 4 and is welded with silicon, thereby bonding the electrodes to the substrate. That is, even after the paste 4 applied to the semiconductor substrate for solar cell (for example, a silicon substrate) to form the electrodes is burnt, a part of a glass component forming the glass powder remains in the electrodes and the glass component is welded with silicon to bond the electrodes to the silicon substrate.

<Second Step>

In the second step, as shown in FIG. 1B, the paste smoothly spread over the screen 3 is filled into the pattern hole 3a of the screen 3 by the filling squeegee 6. At this time, for example, in the case where the filling squeegee 6 is fixed to the scraper 1 and the filling squeegee 6 and the scraper 1 operates in sync with each other nearly simultaneously, when the scraper 1 moves in nearly parallel with the surface of the screen 3 in the first step, following the movement of the scraper 1, the filling squeegee 6 also moves in nearly parallel with the surface of the screen 3. That is, after the start of the first step, the second step is started. While the first step is performed, the first step and the second step are overlappingly performed in terms of time and sequentially finished in this order.

Here, it is preferred that the filling squeegee 6 is made of a flexible material capable of following variation in the thickness of the screen 3 and irregularity of the surface of the object to be printed 5. Furthermore, a material having abrasion resistance and solvent resistance, such as urethane rubber, is preferable as a material for the filling squeegee 6. However, the material is not limited to urethane rubber.

An air cylinder or the like may be used as a means for vertically moving the filling squeegee 6. When the filling squeegee 6 is lowered, by controlling the pressure of compressed air for driving the air cylinder, the pressure with which the paste 4 is filled into the pattern hole 3a of the screen 3 is controlled. For this reason, the amount of the paste 4 filled into the pattern hole 3a can be controlled to a desired amount.

In addition to the air cylinder, a motor may be used as the means for vertically moving the filling squeegee 6. To finely control the amount of the paste 4 filled into the pattern hole 3a with ease, a motor capable of performing numerical control is, though not limited to, especially preferable. Furthermore, to control the amount of the paste 4 filled into the pattern hole 3a, it is more preferable that the position where the paste 4 is pressed by the squeegee 6 can be controlled.

The filling squeegee 6 is set so as to adjust the contact angle with respect to the surface of the screen 3. For example, there is a method of adjusting the moving distance of the motor and a method of adjusting the moving distance of the filling squeegee 6 by providing an angle gauge. The above-mentioned various requirements of the scraper 1 and the filling squeegee 6 enables setting of optimum printing conditions and printing based on the conditions according to the viscosity of the used paste 4 and the shape of the pattern hole 3a provided on the screen 3, that is, the pattern of the paste 4 after printing (also referred to as a “printing pattern”).

<Third Step>

In the third step, as shown in FIG. 1C, first, the scraper 1 and the filling squeegee 6 rise. Then, the object to be printed 5 is sent to a position away from a lower surface of the screen 3 by about 0.05 to 3 mm. The printing squeegee 2 is lowered and pressed against the screen 3, thereby bringing the screen 3 into contact with the object to be printed 5. By moving the printing squeegee 2 in a direction opposite to the scraper 1 (a direction opposite to the moving direction of the scraper 1 in the first step) while bringing the screen 3 into contact with the object to be printed 5, the paste 4 is transferred on the object to be printed 5.

A means similar to the above-mentioned means for moving the scraper 1 and the filling squeegee 6 can be used as a means for vertically and horizontally moving the printing squeegee 2.

Since screen printing is performed by the above-mentioned screen printing method having the first step to the third step, for example, even when the moving speed of the scraper 1 and the filling squeegee 6 is set to be a relatively high speed of 100 mm/sec or more, the paste 4 can be fully filled into the pattern hole 3a provided on the screen 3 and the time required for printing can be greatly reduced. To reduce the time required for printing, it is preferred that the paste 4 is filled into the pattern hole 3a with being spread over the screen 3. That is, the first step and the second step are preferable to be overlappingly performed. Moreover, as the ratio of the time during which the first step and the second step are overlappingly performed to the time during which the first step and the second step are performed is higher, the whole printing time is preferably decreased.

Even when the paste with extremely high viscosity is used for printing of a thick film (that is, printing of a thick coated film of paste), by previously smoothing the paste 4 on the screen 3 by the scraper 1, it becomes easy to fill the paste 4 into the pattern hole 3a of the screen 3 by the filling squeegee 6 and variation in the amount of the paste 4 filled into the pattern hole 3a can be suppressed. As a result, according to printing using the printing squeegee 2, it is possible to prevent a defect in the printed figure (that is, printing shape formed by the conductive paste) from occurring and the film thickness of the pattern of the printed paste 4 from decreasing. Thus, the printed figure can be formed with high accuracy.

Especially in the case as shown in FIG. 3, concerning electrodes provided on the light-receiving surface of a solar cell 7, an electrode pattern is formed of a plurality of long and thin secondary electrodes 9 and primary electrodes 8 which are provided nearly perpendicular to the secondary electrodes 9 and have a larger width than the secondary electrode 9, and to make the light-receiving area larger, each electrode line width needs to be decreased. In such case, the screen printing method in accordance with this embodiment can be preferably used. For example, even when each secondary electrode 9 is formed to have a width of 30 to 120 μm and a length of 10 cm or more and each primary electrode 8 is formed to have a width of 0.5 to 2.5 mm and a length of 10 cm or more, according to the screen printing method in this embodiment, printing of thick film can be achieved without causing breakage of the lines of the secondary electrodes 9.

The present invention is not limited to the above-mentioned embodiment and various modifications and improvements can be made without departing from the scope of the present invention.

For example, it is needless to say that the present invention can be applied to various electrodes in place of the electrodes of the solar cell in the above-mentioned embodiment.

<Working Example>

First, phosphorus was diffused on the light-receiving surface of a silicon substrate 5 (semiconductor substrate) having a specific resistance of 1.5 Ωcm to form a diffusion layer and a silicon nitride film of 850 Å was formed on the diffusion layer as an antireflection coating.

Using a silver paste having a viscosity of 300 Pa·s at the time when a shear rate of 10 s⁻¹ is applied, electrodes were formed according to the screen printing method in the above-mentioned embodiment (that is, the screen printing method shown in FIG. 1A to FIG. 1C).

A screen in which the thickness is 75 μm, the thickness of an emulsion part is 20 μm, the aspect ratio of the pattern hole 3a is 0.5 and mesh size is 230 mesh was used as the screen 3. The aperture ratio of the screen 3 was set to be 60%. A diazo photosensitive emulsion was used as an emulsion. Here, the aspect ratio refers to the ratio of the thickness of the screen 3 to the width of the pattern hole 3a in the shorter direction (that is, thickness/width in the shorter direction of the screen 3). Here, a preferred mode in which the shape of the pattern hole 3a was rectangular and the longitudinal direction of the pattern hole 3a was defined as a printing direction was employed.

A resin material having a rubber hardness of 70 degrees was used as the printing squeegee 2.

Working examples 1 to 5 each have a different speed of the scraper 1. The printing squeegee 2 was moved along a direction shown by an arrow in FIG. 3 to form the primary electrodes 8 and the secondary electrodes 9.

On the other hand, the filling squeegee 6 was not used in comparative examples 1 to 5.

Printing pressure of both the filling squeegee and the printing squeegee (for example, pressure applied to the screen) was set to be 0.15 MPa.

The viscosity of the paste was measured using a rheometer (manufactured by Physica, Inc., type: MCR-300). The paste was subjected to shear rate (here, 10 s⁻¹) for 60 seconds under a constant temperature of 25° C. and after 60 seconds, the viscosity of the paste was measured. The viscosity at the time of the shear rate of 10 s⁻¹ (that is, the time when the paste was subjected to shear rate of 100 was used as data for evaluation.

After drying the substrate on which the paste 4 was printed, the paste 4 was burnt under temperatures up to 700° C. for about 10 minutes and using a microscope, it was observed whether or not a defect occurred in the secondary electrodes of the burnt printing pattern. The thickness of the secondary electrodes after printing, drying and burning was measured using a stylus type surface roughness meter (manufactured by Tokyo Seimitsu Co., Ltd., SURFCOM1400).

Table 1 shows the results.

TABLE 1

| | | | | Thickness | | |
|---|---|---|---|---|---|---|
| | | | | of | Width of | |
| | | Scraper | | secondary | secondary | |
| | Filling | speed | | electrode | electrode | Overall |
| | squeegee | (mm/sec) | Defect | (μm) | (μm) | evaluation |
| Example 1 | Existence | 25 | Absence | 19 | 97 | Δ |
| Example 2 | Existence | 50 | Absence | 19 | 97 | Δ |
| Example 3 | Existence | 100 | Absence | 19 | 98 | ◯ |
| Example 4 | Existence | 150 | Absence | 19 | 98 | ◯ |
| Example 5 | Existence | 200 | Absence | 18 | 97 | ◯ |
| Comparative | Absence | 25 | Absence | 18 | 97 | Δ |
| Example 1 | | | | | | |
| Comparative | Absence | 50 | Small | 16 | 97 | X |
| Example 2 | | | | | | |
| Comparative | Absence | 100 | Existence | 14 | 90 | X |
| Example 3 | | | | | | |
| Comparative | Absence | 150 | Existence | 12 | 85 | X |
| Example 4 | | | | | | |
| Comparative | Absence | 200 | Existence | 9 | 75 | X |
| Example 5 | | | | | | |

As shown in Table 1, in the working examples 1 to 5 using the filling squeegee 6, no defect occurred in the figure pattern (that is, printing pattern) and a thick film of 15 μm or more could be printed even when the speed (moving speed of the scraper 1) was risen. In the comparative examples 1 to 5 using no filling squeegee 6, in the comparative example 1 in which the speed (that is, moving speed of the scraper 1) is 25 mm/sec, no defect occurred in the printing pattern and a thickness of 18 μm could be printed. However, as the speed (that is, moving speed of the scraper 1) was higher, the number of the defects was increased and the thickness of the printing pattern becomes thinner. As described above, high-speed printing could be achieved in the working examples 1 to 5.

The results revealed that the moving speed of the scraper 1 of 100 mm/sec or more, no defect in the printed figure pattern (also referred to as the “printing pattern”, hereinafter) and printing of a thick film of 15 μm or more were suitable conditions for printing the thick film at high speed.

Next, in the above-mentioned examples, the moving speed of the scraper 1 was set at 100 mm/sec and the viscosity of the paste 4 was varied to prepare working examples 6 to 10 and comparative examples 6 to 10. Table 2 shows results of evaluation performed for these examples in the above-mentioned manner.

TABLE 2

| | | | | Thickness | | |
|---|---|---|---|---|---|---|
| | | | | of | Width of | |
| | | Viscosity | | secondary | secondary | |
| | Filling | at 10 s⁻¹ | | electrode | electrode | Overall |
| | squeegee | (Pa · s) | Defect | (μm) | (μm) | evaluation |
| Example 6 | Existence | 420 | Small | 21 | 95 | Δ |
| Example 7 | Existence | 400 | Absence | 21 | 95 | ◯ |
| Example 8 | Existence | 300 | Absence | 19 | 98 | ◯ |
| Example 9 | Existence | 200 | Absence | 15 | 105 | ◯ |
| Example 10 | Existence | 180 | Absence | 14 | 107 | Δ |
| Comparative | Absence | 420 | Large | 16 | 85 | X |
| Example 6 | | | | | | |
| Comparative | Absence | 400 | Large | 16 | 85 | X |
| Example 7 | | | | | | |
| Comparative | Absence | 300 | Existence | 14 | 90 | X |
| Example 8 | | | | | | |
| Comparative | Absence | 200 | Small | 12 | 103 | X |
| Example 9 | | | | | | |
| Comparative | Absence | 180 | Absence | 11 | 105 | X |
| Example 10 | | | | | | |

As shown in Table 2, in the working examples 7, 8 and 9 in which the viscosity of the paste 4 is 200 to 400 Pa·s, no defect was not observed in the printing pattern, the thickness of the secondary electrodes was 15 μm or more and the thick film could be printed. However, in the comparative examples 7, 8 and 9 using no filling squeegee 6, defects occurred in the printing pattern and the thickness of the secondary electrodes became thinner. When the viscosity of the paste 4 exceeded 400 Pa·s, irrespective of presence of the filling squeegee 6, defects occurred in the printing pattern and when the viscosity was less than 200 Pa·s, the thickness was smaller than 15 μm. Accordingly, in the case where the viscosity of the paste 4 was 200 to 400 Pa·s, high-speed printing of the thick film could be achieved.

### <Ideas About Conductive Paste>

So far, the viscosity of the conductive paste for screen printing has been often measured only using a rotational viscometer. However, the viscosity of the conductive paste measured with a certain number of revolutions is the viscosity under the shear rate at one point. It is extremely difficult to estimate viscoelastic behavior of the conductive paste in the screen printing during which the shear rate applied to the conductive paste varies every moment.

Since the conductive paste is a viscoelastic body, it is estimated that a viscous component (that is, the viscous component of viscosity) and an elastic component (that is, the elastic component of viscosity) in each conductive paste greatly affect printing performance. However, it is impossible to evaluate viscoelasticity by using the rotational viscometer.

Therefore, in the preferred embodiment of the present invention, by using the rheometer, the viscosity of the conductive paste when the shear rate applied to the conductive paste varied every moment, and the viscous component (that is, the viscous component of viscosity) and the elastic component (that is, the elastic component of viscosity) in the conductive paste were controlled to design the conductive paste in the preferred embodiment of the present invention.

For the conductive paste in the preferred embodiment of the present invention, to measure variation in the viscosity of the conductive paste and dynamic viscoelastcity when the shear rate was continuously varied, the conductive paste was disposed between two disks or cones of a measuring part and subjected to the shear rate (that is, distortion) and stress occurring in the conductive paste was measured.

According to the present invention, by measuring variation in the viscosity of the conductive paste when the shear rate was varied from 0 to 40 s⁻¹ under 25° C. as well as a storage elastic modulus and a loss elastic modulus when the distortion was varied from 0 to 20% under a frequency of 1 Hz, the storage elastic modulus and the loss elastic modulus in the range of distortion were acquired. In other words, an arbitrary shear rate in the range of 0 to 40 s⁻¹ (for example, 10 s⁻¹, 40 s⁻¹) was adopted and the viscosity in the state where the adopted constant shear rate was applied to the conductive paste at 25° C. for a predetermined period was measured.

When the viscosity of the conductive paste is extremely high, there are some cases where printing cannot be performed due to release property of the conductive paste from a printing plate (that is, the screen) (for example, release property from the mesh part of the pattern hole). On the contrary, when the viscosity of the conductive paste is extremely low, there are some cases where the thick film cannot be formed due to bleeding after printing (that is, bleeding in the printing pattern of the conductive paste). In consideration with these situations, it is deemed that the viscosity of the conductive paste needs to fall between a certain range. It is preferred that the certain range of the viscosity is between 200 Pa·s and 350 Pa·s in the case of the shear rate of 10 s⁻¹ and between 80 Pa·s and 120 Pa·s in the case of the shear rate of 40 s⁻¹.

However, only by placing the viscosity within the range, problems such as bleeding after printing and clogging of the conductive paste into the mesh part of the printing plate cannot be solved.

Therefore, the storage elastic modulus G′ and the loss elastic modulus G″ in the case where the distortion was varied between 0 to 20% at the frequency of 1 Hz were measured. Then, it was confirmed that when a point where values of the measured storage elastic modulus G′ and the loss elastic modulus G″ were reversed in the above-mentioned range (that is, the range of 0 to 20% in distortion), that is, a gel point existed, the thick film could be formed while preventing clogging of the mesh part of the printing plate without generating bleeding in the printing pattern after printing.

When a sine wave as distortion is applied to samples of such conductive paste, the elastic component remains the same phase and the viscous component is shifted in phase by 90 degrees. By utilizing the fact, viscoelasicity of the conductive paste can be divided into the elastic and viscous components and measured separately. Frequency needs to be set within the range in which the conductive paste can respond linearly (that is, within the range in which distortion can respond linearly to stress). It was confirmed that the plurality of conductive pastes used for evaluation had the range of linear response (that is, the range in which distortion can respond linearly to stress) of 0 to 5 Hz in the case of distortion of 0.1%. Accordingly, in measuring dynamic viscoelasicity, evaluation was made noting 1.0 Hz within the range in which the conductive paste can respond linearly. The reason why the measuring range of distortion was set as 0 to 20% was that if measurement is made in this range, most printing conductive paste could be measured from the range in which linear response was possible to the range in which change in elasticity and viscosity occurred.

In the range in which the conductive paste can respond linearly, when the storage elastic modulus G′ is larger than the loss elastic modulus G″, the conductive paste becomes an elastic body and thus is hard to flow. As a result, the conductive paste is hard to flow during printing and the release property of the printing plate is extremely poor. However, no bleeding (that is, bleeding of the printing pattern) occurs.

On the contrary, in the range in which the conductive paste can respond linearly, when the storage elastic modulus G′ is smaller than loss elastic modulus G″, the viscosity of the conductive paste (that is, viscous component of the viscosity) is too strong compared to the elasticity (that is, elastic component of the viscosity). For this reason, the conductive paste is very easy to flow, dripping in the printed coated film (that is, the coated film of the conductive paste) occurs due to leveling and bleeding becomes larger. However, the release property of the printing plate is improved and clogging of the paste into the mesh part of the printing plate can be suppressed.

Therefore, in varying distortion from 0 to 20%, the conductive paste in accordance with the preferred embodiment of the present invention having a gel point where values of the storage elastic modulus G′ and the loss elastic modulus G″ are reversed is used, the conductive paste has these two characteristics (that is, the characteristic that the storage elastic modulus G′ is larger than the loss elastic modulus G″ in the range in which the conductive paste can respond linearly and the characteristic that the storage elastic modulus G′ is smaller than the loss elastic modulus G″ in the range in which the conductive paste can respond linearly). Thus, it was confirmed that when screen printing is performed by using the conductive paste, bleeding after printing (that is, bleeding of the printing pattern) as well as clogging of the paste into the mesh part of the printing plate could be suppressed, the paste could be easily separated from the plate and the printing paste (that is, printing pattern) could be easily made thicker.

It is preferred that the ratio of the storage elastic modulus G′ and loss elastic modulus G″ (G″/G′=tan δ) in the range of linear response falls within the range from 0.4 to 1.2. When the ratio is less than 0.4, the release property of the printing plate is extremely poor and thus, clogging into the mesh part of the printing plate cannot be suppressed. When the ratio is more than 1.2, unpreferably, dripping on the printed coated film is generated, bleeding becomes larger and the film cannot be made thicker.

The solar cell using the conductive paste in accordance with the preferred embodiment of the present invention can be manufactured according to a publicly known manufacturing method by using the conductive paste in accordance with the preferred embodiment of the present invention for forming electrodes.

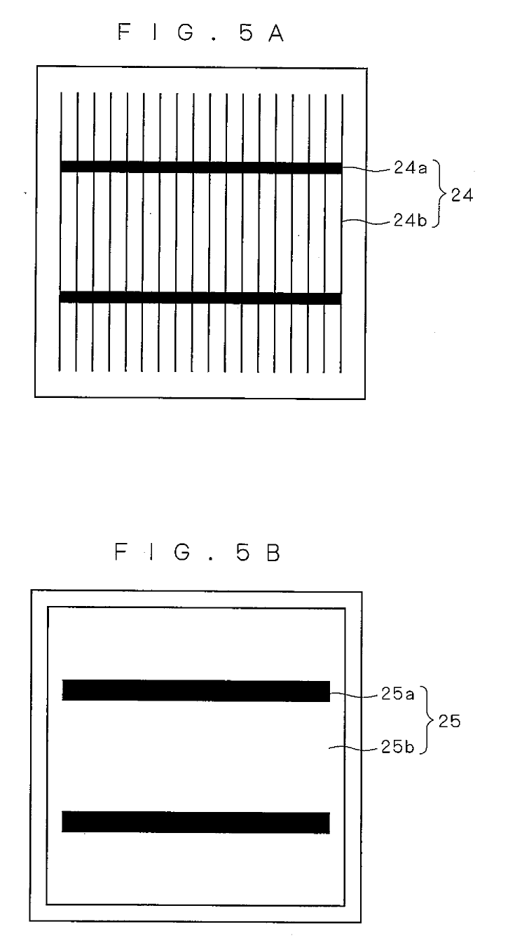

The solar cell in accordance with the preferred embodiment of the present invention will be described with reference to appended figures. FIG. 4 is a sectional view showing configuration of the solar cell in accordance with the preferred embodiment of the present invention. FIG. 4 shows a semiconductor substrate 21, a diffusion layer 22, an antireflection coating 23, front electrodes 24, back electrodes 25 and a back electric field area 26. That is, the solar cell in accordance with the preferred embodiment of the present invention is configured to have the semiconductor substrate 21, the diffusion layer 22, the antireflection coating 23, the front electrodes 24, the back electrodes 25 and back electric field area 26. Hereinafter, a method of manufacturing the solar cell in accordance with the preferred embodiment of the present invention will be described.

First, the semiconductor substrate 21 is prepared. The semiconductor substrate 21 is a substrate that contains conductive semiconductor impurities such as boron (B) and has a specific resistance of 0.2 to 2.0 Ω·cm. The semiconductor substrate 21 is formed by a pulling method in the case of a monocrystal silicon substrate and by a casting method in the case of a polycrystal silicon substrate. The polycrystal silicon substrate enables mass production and is superior to the monocrystal silicon substrate in terms of manufacturing costs. An ingot formed by the pulling method or the casting method is cut into pieces of an appropriate size such as 10 cm×10 cm or 15 cm×15 cm and sliced to have a thickness of 500 μm or less, more preferably, 300 μm to form the semiconductor substrate 21.

Subsequently, to clean the cut surface of the substrate (semiconductor substrate 21), the front surface (the surface of the semiconductor substrate 21) is minutely etched with NaOH, KOH, fluorinated acid or fluoro-nitric acid.

Then, to effectively take light into the substrate (semiconductor substrate 21), it is desired that minute protrusions are formed on the front surface as the light-receiving surface of the semiconductor substrate 21 by a dry etching method or a wet etching method.

Next, by disposing the semiconductor substrate 21 in a diffusion furnace and heat treating the semiconductor substrate 21 in gas containing an impurity element such as phosphorous oxychloride, phosphorus atoms are diffused on the front surface of the semiconductor substrate 21 to form the n-conductive type diffusion layer 22 having a sheet resistance of about 30 to 300 Ω/□ and a thickness of about, 0.2 to 0.5 μm.

The n-type diffusion layer 22 remains only on the front surface of the semiconductor substrate 21 and the other region (that is, the n-type diffusion layer 22 formed on the surface other than the front surface of the semiconductor substrate 21) is removed. After that, the semiconductor substrate 21 is washed with purified water. The n-type diffusion layer 22 formed on the region other than the front surface of the semiconductor substrate 21 is removed, for example, by applying a resist film on the front surface of the semiconductor substrate 21 and etching the diffusion layer 22 by using a mixed liquid of fluorinated acid and nitric acid (that is, etching treatment of the n-type diffusion layer 22) and removing the resist film.

The antireflection coating 23 is further formed on the side of the front surface of the semiconductor substrate 21. The antireflection coating 23 is formed of, for example, a silicon nitride film and made by a plasma CVD method of changing mixed gas of silane and ammonia to plasma through glow discharge decomposition and accumulating it. In consideration with a difference between the antireflection coating 23 and the semiconductor substrate 21 in refraction index, the antireflection coating 23 is formed to have a refraction index of about 1.8 to 2.3 and a thickness of about 500 to 1000 Å. The silicon nitride film brings about passivation effect and improves electrical characteristics of the solar cell together with the antireflectional function.

By applying silver paste on the front surface and aluminum paste and silver paste on the back surface of the semiconductor substrate 21 and burning both surfaces, the front electrodes 24 and the back electrodes 25 are formed simultaneously.

The conductive paste in accordance with the preferred embodiment of the present invention contains conductive metal powder having conductivity such as silver, an organic vehicle formed by dissolving an organic binder in an organic solvent and an additive for improving dispersibility of the conductive metal powder and maintaining stability of dispersion. A gel point exists in the range where the conductive paste responds linearly at 1 Hz when distortion of 0 to 20% is applied (that is, distortion is repeatedly varied from 0 to 20% at 1 Hz).

It is preferred that the conductive paste in accordance with the preferred embodiment of the present invention uses scale-like powder of about 3 to 10 μm and spherical powder of about 0.1 to 1.0 μm as the conductive metal powder and contains the conductive metal powder in the range of 70 to 90 weight % of the paste weight (that is, the whole weight of the conductive paste). Alternatively, the conductive paste may contain glass powder. In this case, it is preferred that grain size of solid component formed of the conductive metal powder and the glass powder is controlled to be within the range of about 0.1 to 10 μm, the sum of the conductive metal powder and the glass powder is contained in the range of 70 to 90 weight % of the paste weight and the glass powder is contained in the range of 2 to 8 weight % of the paste weight. When the solid component of 70 weight % or more is contained, excessive viscosity tendency of the conductive paste (that is, the tendency toward dominant viscous component in viscosity) lowers, thereby suppressing the state where printing bleeding (that is, bleeding of the printing pattern) is easy to occur. On the contrary, the solid component of 90 weight % or less is contained, excessive elasticity tendency of the conductive paste (that is, the tendency toward dominant elastic component in viscosity) lowers, thereby suppressing the state where the paste is easy to clog in the pattern hole. As described above, by adjusting grain size distribution and content to be within the above-mentioned range, the conductive paste having the gel point can be manufactured.

However, when the range of grain size distribution of the solid component is 0.01 to 1.0 μm, excessive elasticity tendency is caused by an increase in area/weight ratio (that is, specific surface) and the conductive paste is easy to clog the pattern hole. On the contrary, when the range of grain size distribution of the solid component is 5 to 20 μm, excessive viscosity tendency is caused by a decrease in area/weight ratio and the printing bleeding is easy to occur.

It is preferred that the organic vehicle contains the organic binder of 1 to 6 weight %. When the organic binder of 1 weight % or more and 6 weight % or less is contained, viscosity of the organic vehicle formed by dissolving the organic binder in the organic solvent becomes appropriate and viscosity of the conductive paste can satisfy the requirement that the viscosity falls within the range of 200 Pa·s to 350 Pa·s when shear rate of 10 s⁻¹ is applied and within the range of 80 Pa·s to 120 Pa·s when shear rate of 40 s⁻¹ is applied.

It is preferred that the additive is contained in the range of 0.5 to 1.7 weight % of the paste weight. The additive contributes to improvement in dispersibility of the conductive metal powder and stability of dispersion in the conductive paste. When the additive is less than 0.5 weight %, since the dispersion effect is not enough, the agglomeration of metal powder is easy to occur and the paste has a very strong elasticity tendency. On the contrary, when the additive is more than 1.7 weight %, interfacial energy in the conductive paste lowers and the paste has a very strong viscosity tendency.

The organic solvent used in the conductive paste in accordance with the preferred embodiment of the present invention includes butyl carbitol, butyl carbitol acetate, buthyl cellosolve, buthyl cellosolve acetate, terpinenol, hydrogenated terpinenol, hydrogenated terpineol acetate, methyl ethyl ketone, isobornyl acetate, nopyl acetate or the like. The organic binder includes cellulosic resin such as methyl cellulose, ethyl cellulose and cellulose nitrate, acrylic resin such as methyl methacrylate, butyral resin or the like. The additive includes anionic and nonionic dispersants, surface-active agents or the like.

Since the organic vehicle used in this embodiment is dissolved and vaporized under about 400° C., the component does not remain in the burned electrodes 24, 25. Glass frit is used to add strength to the burned electrodes 24, 25. The glass frit contains oxides of lead, boron and silicon and may have various softening points of 300 to 600° C. After burning, since a part of the glass frit remains in the electrodes 24, 25 and another part of the glass frit is welded to silicon, the glass frit has a function of bonding the electrodes 24, 25 to the silicon substrate (semiconductor substrate 21).

When the thick film with thin lines is continually printed at high speed, it is guessed that the ratio of the storage elastic modulus G′ to the loss elastic modulus G″ have an effect on bleeding of the conductive paste or failure in the shape due to clogging into the mesh part. Especially since printing is continually performed at high speed, bleeding of the conductive paste after printing becomes prominent.

Therefore, by manufacturing the conductive paste having the gel point where the storage elastic modulus G′ and the loss elastic modulus G″ intersect each other in the range where the conductive paste responds linearly at 1 Hz when distortion of 0 to 20% is applied (that is, distortion is repeatedly varied from 0 to 20% at 1 Hz), bleeding of the printing pattern can be prevented.

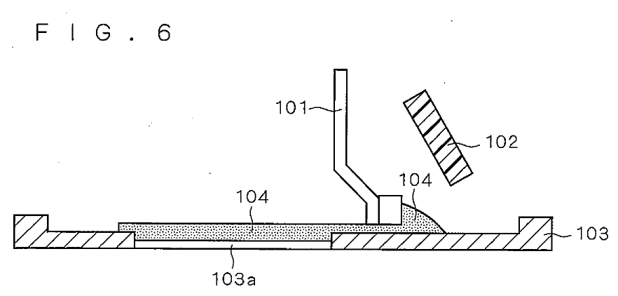

As shown in FIG. 5A, the front electrode 24 is formed of bus bar electrodes (hereinafter referred to as “front surface bus bar electrodes”) 24a for taking out an output from the front surface and current-collecting finger electrodes (hereinafter referred to as “current-collecting front surface finger electrodes”) 24b provided to be perpendicular to the front surface bus bar electrodes 24a. As shown in FIG. 5B, the back electrode 25 is formed of a bus bar electrodes (hereinafter referred to as “back surface bus bar electrodes”) 25a for taking out an output from the back surface and a collecting electrode (hereinafter referred to as “back surface collecting electrode”) 25b.

The back surface collecting electrode 25b is printed as follows: paste-like aluminum paste formed by adding (mixing) aluminum powder as the conductive metal powder, the organic vehicle and the glass powder is applied to the semiconductor substrate 21, for example, by a screen printing method, dried and burned for 1 to 30 minutes to reach maximum temperature of 600 to 800° C. after drying. At this time, aluminum is diffused in the semiconductor substrate 21 to form the back electric field area 26 for preventing recombination of carriers generated in the back surface. The back electric field area 26 is also referred to as BSF (Back Surface Field) and prevents a decrease in the efficiency due to recombination of light-generating carriers in the vicinity of the back surface of the semiconductor substrate 21.

The front surface bus bar electrodes 24a, the front surface finger electrodes 24b and the back surface bus bar electrode 25a are printed as follows: paste-like silver paste formed by adding (mixing) silver powder as the conductive metal powder, the organic vehicle and the glass frit is applied to the semiconductor substrate 21, for example, by a screen printing method, dried and burned for 1 to 30 minutes to reach maximum temperature of 600 to 800° C. after drying. As a method of applying the conductive paste to the semiconductor substrate 21, publicly known methods other than the screen printing method may be employed. The front electrodes 24 may be formed after removing the area corresponding to electrodes on the antireflection coating 23 by etching. Alternatively, the front electrodes 24 may be formed directly on the antireflection coating 23 by a method called as fire-through.

After forming of the back surface bus bar electrode 25a for taking out the output, the back surface collecting electrode 25b is formed so as not to cover a part of the back surface bus bar electrode 25a. The order of forming the back surface bus bar electrode 25a and back surface collecting electrode 25b may be reversed. The back electrodes 25 need not have the above-mentioned configuration and may be formed of bus bar electrodes and finger electrodes that contain silver as a main component.

Since the electrodes of the solar cell manufactured by using the conductive paste in accordance with the preferred embodiment of the present invention prevents clogging in the mesh part of the printing plate, productivity is not lowered, bleeding after printing can be suppressed and the printed paste (that is, printing pattern) can be made thicker. For this reason, since especially the front surface finger electrodes 24b of the solar cell can be made small in width and large in thickness, resistance loss of the front surface finger electrode can be suppressed without reducing light-receiving area. As a result, the solar cell having high efficiency (that is, high conversion efficiency) can be formed. Furthermore, by adopting the above-mentioned ideas on screen printing and the conductive paste in combination, the solar cell having further higher efficiency can be formed.

### <Working Example>

[Manufacturing of Paste]

First, butyl carbitol acetate as the organic solvent, butyral resin as the organic binder and nonionic dispersing agent as the additive were mixed and dissolved to prepare the organic vehicle. The prepared organic vehicle, the glass powder and the silver powder were mixed and uniformly dispersed by using a three-roll to prepare the conductive paste.

[Measurement of Paste Viscosity]

The viscosity of the conductive paste in these working examples was measured while varying the shear rate. For measurement, a rheometer (manufactured by Physica, Inc., type:MCR-300) was used. As measurement conditions, the shear rate of 10 s⁻¹ and 40 s⁻¹ was applied to the conductive paste under a constant temperature of 25° C. for 60 seconds and the viscosity after 60 seconds was measured. Specifically, the shear rate of 10 s⁻¹ was continually applied to the conductive paste under a constant temperature of 25° C. for 60 seconds and after 60 seconds, the viscosity of the conductive paste was measured with applying the shear rate of 10 s⁻¹ to the conductive paste. Also, the shear rate of 40 s⁻¹ was continually applied to the conductive paste under a constant temperature of 25° C. for 60 seconds and after 60 seconds, the viscosity of the conductive paste was measured with applying the shear rate of 40 s⁻¹ to the conductive paste.

[Measurement of Ratio tan δ of Storage Elastic Modulus G′ to Loss Elastic Modulus G″ of Paste]

The dynamic viscoelasicity of the conductive paste in these working examples was measured. For measurement, the above-mentioned rheometer was used. As measurement conditions, the storage elastic modulus G′ and the loss elastic modulus G″, respectively, were measured while varying distortion applied to the conductive paste from 0 to 20% under a constant temperature of 25° C. at the frequency of 1 Hz. That is, while repeatedly varying the distortion applied to the conductive paste from 0 to 20% at the frequency of 1 Hz, the storage elastic modulus G′ and the loss elastic modulus G″, respectively, were measured.

[Configuration of Solar Cell]

A damage layer of the front surface of the polycrystal silicon p-type semiconductor substrate 21 having 250 μm in thickness, 15 cm×15 cm in shape and 1.5 Ω·cm in resistance was etched with NaOH and washed. Next, by disposing the semiconductor substrate 21 in the diffusion furnace and heating the semiconductor substrate 21 in phosphorous oxychloride (POCl3), phosphor atoms were diffused on the front surface of the semiconductor substrate 21 to form the n-type diffusion layer 22. Then, a silicon nitride film having a thickness of 850 Å as the antireflection coating 23 was formed on the diffusion layer 22 by a plasma CVD method.

Next, aluminum paste was applied over the back surface of the semiconductor substrate 21 to form the back electric field area 26. The aluminum paste was removed by ultrasonic cleaning. That is, the aluminum paste was used to form the back electric field area 26.

The conductive paste thus prepared was applied on the side of the front surface and the back surface of the semiconductor substrate 21 as shown in FIG. 5A according to the screen printing method using the screen of 230 mesh with the printing pattern hole having the thickness of 20 μm in the emulsion part and the resin squeegee having the rubber hardness of 70 degrees and dried. The grid-like printing pattern was formed on the side of the back surface like the front surface.

[Research of Bleeding and Defect of Printed Figure Pattern]

In the figure pattern printed on the semiconductor substrate 21 by using the printing pattern shown in FIG. 5A, the width of the front surface finger electrode 24b having a designed line width of 100 μm was observed with an optical microscope and measured. A possible defect was also observed with the optical microscope.

[Research of Clogging in Mesh Part of Pattern Hole After Printing]

To research possible clogging in the mesh part of the pattern hole, the pattern hole was observed with the optical microscope from the side of the back surface after printing.

[Research of Film Thickness and Difference Between Central Part and End Parts of Printed Figure Pattern]

The film thickness of the printed front surface finger electrode 24b was measured. Measurement is made by using a stylus type surface roughness meter made by Tokyo Seimitsu Co., Ltd.

Table 4 shows measurement results of viscosity, the presence or absence of the point where the storage elastic modulus G′ and the loss elastic modulus G″ intersect each other, that is, the gel point, the amount of bleeding, the presence or absence of the clogging and defect and measurement results of the thickness of the front surface finger electrode, in the case where the conductive paste of samples 1 to 11 shown in Table 3. Among the results, the amount of bleeding of 15 μm or less, no defect in the printed printing pattern and the film thickness of 15 μm or more were assumed as requirements of the conductive paste having excellent printing property. In Tables 3 and 4, the sample numbers with a sign * does not fall within the scope of the present invention (that is, conductive paste other than the conductive paste in accordance with the preferred embodiment of the present invention) and the other sample numbers falls within the scope of the present invention (that is, the conductive paste in accordance with the preferred embodiment of the present invention).

TABLE 3

| | | Powder amount | Solvent | Resin | Additive |
|---|---|---|---|---|---|
| Sample | Grading | (metal + glass) | amount | amount | amount |
| 1 | 0.1-10 μm | 80 | 14.5 | 4 | 1.5 |
| *2 | 0.01-1 μm | 80 | 14.5 | 4 | 1.5 |
| *3 | 5-20 μm | 80 | 14.5 | 4 | 1.5 |
| *4 | 0.1-10 μm | 70 | 24.5 | 4 | 1.5 |
| 5 | 0.1-10 μm | 85 | 9.5 | 4 | 1.5 |
| 6 | 0.1-10 μm | 90 | 4.5 | 4 | 1.5 |
| *7 | 0.1-10 μm | 92 | 2.5 | 4 | 1.5 |
| *8 | 0.1-10 μm | 80 | 18 | 0.5 | 1.5 |
| *9 | 0.1-10 μm | 80 | 11 | 7.5 | 1.5 |
| *10 | 0.1-10 μm | 80 | 15.75 | 4 | 0.25 |
| *11 | 0.1-10 μm | 80 | 13.25 | 4 | 2.75 |

TABLE 4

| | | | | | Bleeding amount | | | Thickness of |
|---|---|---|---|---|---|---|---|---|
| | Overall | Viscosity at | Viscosity at | | of finger | | | finger |
| Sample | evaluation | 10 s⁻¹ (Pa · s) | 40 s⁻¹ (Pa · s) | Gel point | electrode (μm) | Clogging | Defect | electrode (μm) |
| 1 | ◯ | 330 | 110 | Existence | 8 | Absence | Absence | 18 |
| *2 | X | *380 | *140 | Existence | 5 | *Existence | *Existence | 20 |
| *3 | X | *190 | *70 | *Absence | *17 | Absence | Absence | *12 |
| *4 | X | 200 | 80 | *Absence | *20 | Absence | Absence | *12 |
| 5 | ◯ | 330 | 110 | Existence | 7 | Absence | Absence | 22 |
| 6 | ◯ | 350 | 120 | Existence | 5 | Absence | Absence | 24 |
| *7 | X | *400 | *150 | Existence | 5 | *Existence | *Existence | 25 |
| *8 | X | *100 | *50 | *Absence | *20 | Absence | Absence | *9 |
| *9 | X | *380 | *130 | Existence | 8 | *Existence | *Existence | 22 |
| *10 | X | *450 | *200 | Existence | 5 | *Existence | *Existence | 18 |
| *11 | X | 200 | *70 | *Absence | *16 | Absence | Absence | *12 |

Here, noting the viscosity at the shear rate of 10 s⁻¹ and 40 s⁻¹ and the gel point, the samples of the sample numbers 1, 5 and 6 were the conductive paste that satisfied the requirements of the viscosity in the range of 200 Pa·s to 350 Pa·s at the shear rate of 10 s⁻¹ and in the range of 80 Pa·s to 120 Pa·s at the shear rate of 40 s⁻¹ and the presence of the gel point. When the samples of the sample numbers 1, 5 and 6 were used (that is, in this working examples), no clogging and defect was observed and excellent printing property could be obtained

However, when the conductive paste of samples of the sample numbers 2, 7, 9 and 10 having the viscosity of 350 Pa·s or more at the shear rate 10 s⁻¹ and 120 Pa·s or more at the shear rate 40 s⁻¹ were adopted (that is, in the comparative examples), clogging and defect were observed.

When the conductive paste of samples of the sample numbers 3, 4, 8 and 11 having the viscosity of 200 Pa·s or less at the shear rate 10 s⁻¹ and 120 Pa·s or less at the shear rate 40 s⁻¹ and the absence of the gel point were adopted (that is, in the comparative examples), the amount of bleeding of the finger electrodes was larger than 15 μm and the thickness of the finger electrode was smaller than 15 μm.

As described above, by controlling the conductive paste to have the viscosity in the range of 200 Pa·s to 350 Pa·s at the shear rate of 10 s⁻¹ and in the range of 80 Pa·s to 120 Pa·s at the shear rate of 40 s⁻¹, it was possible to prevent clogging of the conductive paste in the mesh part and defect of the formed conductive paste film from occurring. Furthermore, by measuring values of the storage elastic modulus G′ and the loss elastic modulus G″ while varying the distortion applied to the conductive paste at the frequency of 1 Hz from 0 to 20% and setting the conductive paste to have the point where magnitudes of the measurement values of the storage elastic modulus G′ and the loss elastic modulus G″ in the above-mentioned range of distortion are reversed, that is, the gel point, no bleeding in the printed printing pattern occurs. Moreover, by using the conductive paste that satisfies the above-mentioned requirements (requirements about viscosity and gel point), the thick film of the conductive paste can be formed as designed.

[Research of Characteristics of Paste After Printing and Burning]

The semiconductor substrate 21 on which the conductive paste of the samples with the sample numbers 1 to 11 was printed was burned up to 750° C. for about 5 minutes to prepare the solar cells.

Measurement results of various characteristics of the solar cells are shown in the following table.

TABLE 5

| | Short-circuit | Open voltage | | Conversion |
|---|---|---|---|---|
| Sample | current (mA) | (V) | Fill factor (FF) | efficiency (%) |
| 1 | 8172 | 0.612 | 0.748 | 16.09 |
| 2 | 8189 | 0.611 | 0.711 | 15.30 |
| 3 | 8138 | 0.609 | 0.734 | 15.65 |
| 4 | 8129 | 0.611 | 0.735 | 15.70 |
| 5 | 8175 | 0.611 | 0.752 | 16.16 |
| 6 | 8184 | 0.612 | 0.756 | 16.29 |
| 7 | 8192 | 0.610 | 0.692 | 14.87 |
| 8 | 8130 | 0.610 | 0.729 | 15.55 |
| 9 | 8170 | 0.609 | 0.716 | 15.32 |
| 10 | 8194 | 0.611 | 0.684 | 14.73 |
| 11 | 8141 | 0.611 | 0.732 | 15.66 |

The conductive paste of the samples with the sample numbers 1, 5 and 6 had the viscosity in the range of 200 Pa·s to 350 Pa·s at the shear rate of 10 s⁻¹ and in the range of 80 Pa·s to 120 Pa·s at the shear rate of 40 s⁻¹, and when the values of the storage elastic modulus G′ and the loss elastic modulus G″ was measured while varying the distortion applied to the conductive paste at the frequency of 1 Hz from 0 to 20%, the point where magnitudes of the measured values of the storage elastic modulus G′ and the loss elastic modulus G″ were reversed, that is, the gel point was detected. As apparent from Table 5, with the solar cells prepared by using the conductive paste of the samples with the sample numbers 1, 5 and 6, the conversion efficiency exceeding 16% was obtained. Therefore, it was revealed that the conversion efficiency could be improved by suppressing the amount of bleeding, of the printed conductive paste and ensuring the film thicker.

While the invention has been shown and described in detail, the foregoing description is in all aspects illustrative and not restrictive. It is therefore understood that numerous modifications and variations can be devised without departing from the scope of the invention.

1-18. (canceled)

19. A method of manufacturing a solar cell, comprising:
(a) spreading a conductive paste on a screen by using a scraper so as to cover a pattern hole of the screen;
(b) filling the conductive paste spread on the screen into the pattern hole by using a filling squeegee;
(c) printing the conductive paste filled into the pattern hole on an object to be printed for a solar cell by using a printing squeegee,
(d) burning the conductive paste printed on the object.

20. The method according to claim 19, wherein
the conductive paste has characteristics that a viscosity falls within a range of 200 Pa·s to 350 Pa·s when a shear rate of 10 s⁻¹ is applied and within a range of 80 Pas to 120 Pa·s when a shear rate of 40 s⁻¹ is applied under 25° C., and magnitudes of a storage elastic modulus G′ and a loss elastic modulus G″ are reversed when distortion applied to the conductive paste at a frequency of 1 Hz is varied from 0 to 20%.

21. The method according to claim 19, wherein the conductive paste contains a metal powder and an organic vehicle, and has a viscosity of 200 Pa·s to 400 Pa·s when a shear rate of 10 s⁻¹ is applied under 25°C.

22. The method according to claim 19, wherein an aspect ratio of the pattern hole is 0.5 or more.

23. The method according to claim 19, wherein
the step (a) comprises:
(a-1) moving the scraper in nearly parallel with a front surface of the screen with a predetermined distance from the screen.

24. The method according to claim 19, wherein
the step (b) comprises:
(b-1) moving the filling squeegee with the conductive paste being pressed against the screen.

25. The method according to claim 19, wherein a moving speed of the scraper in the step (a) and a moving speed of the filling squeegee in the step (b) are each 100 mm/sec or more.
